(19) United States
(12) Patent Application Publication
(10) Pub. No.: US 2023/0422399 A1
(43) Pub. Date: Dec. 28, 2023

(54) METHODS AND SYSTEMS FOR IMPLEMENTING A MODULAR PLATFORM IMPLEMENTING ACTIVE DEVICES

(71) Applicant: WOLFSPEED, INC., Durham, NC (US)

(72) Inventors: Adam ANDERS, Cary, NC (US); Julius RICE, Wake Forest, NC (US); Bart GARROTT, Apex, NC (US)

(21) Appl. No.: 17/848,526

(22) Filed: Jun. 24, 2022

(51) Int. Cl. H05K 1/14; H05K 1/02

(52) U.S. Cl. CPC H05K 1/141; H05K 1/0268; H01R 12/737

(57) ABSTRACT

A modular platform includes a mother board and at least one daughter board. The at least one daughter board includes at least one active device; and the at least one daughter board includes measurement circuitry. The mother board is configured to operate with a plurality of different implementations of the at least one daughter board; and where the plurality of different implementations of the at least one daughter board includes different configurations and/or types of the at least one active device.

### BACKGROUND OF THE DISCLOSURE

Typical systems implementing active devices, such as evaluation systems, are designed and configured for operation with specific components and devices. Accordingly, it is not possible to implement the typical systems with alternative devices. For example, an evaluation system is typically designed with and configured for specific components and devices, such as gate driver circuits. Accordingly, it is not possible to test alternative gate driver circuits. Similarly, an evaluation system is typically designed with and configured for specific components and devices, such as power devices. Accordingly, it is not possible to test alternative power devices.

Accordingly, what is needed is methods and systems configured for implementing different components and devices.

### SUMMARY OF THE DISCLOSURE

One aspect includes a modular platform that includes a mother board; at least one daughter board; the at least one daughter board includes at least one active device; and the at least one daughter board includes measurement circuitry, where the mother board is configured to operate with a plurality of different implementations of the at least one daughter board; and where the plurality of different implementations of the at least one daughter board includes different configurations and/or types of the at least one active device.

One aspect includes a method of implementing a modular platform that includes providing a mother board; providing at least one daughter board; configuring the at least one daughter board with at least one active device; and configuring the at least one daughter board with measurement circuitry; and configuring the mother board to operate with a plurality of different implementations of the at least one daughter board, where the plurality of different implementations of the at least one daughter board includes different configurations and/or types of the at least one active device.

One aspect includes an apparatus that includes a mother board; at least one daughter board; and the at least one daughter board includes at least one active device, where the modular platform is configured to be implemented in a product to facilitate high-power density by placing the at least one active device on or in the at least one daughter board such that a surface of the at least one daughter board is perpendicular to a surface of the mother board.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a front view of a modular platform according to aspects of the disclosure.

FIG. 2 illustrates a top view of a modular platform according to FIG. 1.

FIG. 3 illustrates a top perspective view of a modular platform according to FIG. 1.

FIG. 4 illustrates a front perspective view of a modular platform according to FIG. 1.

FIG. 5 illustrates a side view of a modular platform according to FIG. 1.

FIG. 6 illustrates another front view of a modular platform according to FIG. 1.

FIG. 7 illustrates a top view of a modular platform according to FIG. 1.

FIG. 8 illustrates a cross-sectional view of the mother board according to FIG. 1.

FIG. 9 illustrates a top view of the mother board according to FIG. 1.

FIG. 10 illustrates a view of the intermediate layer according to FIG. 1.

FIG. 11 illustrates a bottom view of the lower layer 218 according to FIG. 1.

FIG. 12 illustrates a front view of an exemplary implementation of the at least one daughter board according to aspects of the disclosure.

FIG. 13 illustrates a back view of an exemplary implementation of the at least one daughter board according to aspects of the disclosure.

FIG. 14 illustrates a side view of an exemplary implementation of the at least one daughter board according to aspects of the disclosure.

FIG. 15 illustrates a partial front view of an exemplary implementation of the at least one daughter board according to FIG. 12.

FIG. 16 illustrates a front view of another exemplary implementation of the at least one daughter board according to aspects of the disclosure.

FIG. 17 illustrates a side view of an exemplary implementation of the at least one daughter board according to aspects of the disclosure.

FIG. 18 illustrates a bottom view of an exemplary implementation of the at least one daughter board according to aspects of the disclosure.

FIG. 18 illustrates a process of implementing and operating the modular platform according to aspects of the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

This disclosure is directed to methods and systems for implementing a modular platform configured for operation with multiple different device implementations of active devices. For example, the disclosed methods and systems may be implemented as an evaluation platform configured for testing active devices including transistors, diodes, control devices, and/or the like. For example, transistors such as silicon carbide (SiC) metal-oxide-semiconductor field-effect transistors (MOSFETs), silicon (Si) MOSFETS, insulated-gate bipolar transistors (IGBTs), and/or the like; diodes such as SiC diodes, SiC Schottky diodes, Si diodes, and/or the like; and control devices such as a controller, gate drive circuits, and/or the like.

The modular platform may be configured such that the evaluation system is broken down into modular pieces, separating out various components, such as the power switching devices, the gate driver, the control, the DC Bus, and/or the like making it easier to test components in different configurations. The disclosed modular platform may allow users to very easily test active devices including transistors, such as MOSFETs, diodes, and/or the like in different packages, different current ratings, and/or the like. Additionally, users can implement the modular platform to work with a range of different associated devices, such as different gate drivers, different gate power supply options, different power supply options, and/or the like.

The modular platform may be used in a product to facilitate high-power density by placing the power devices on a daughter card perpendicular to the main board. The modular platform may also be used to facilitate easy manufacturing and repair of a power converter and/or the like. The modular platform may leverage economies of scale by building a common power card that can be used in many applications.

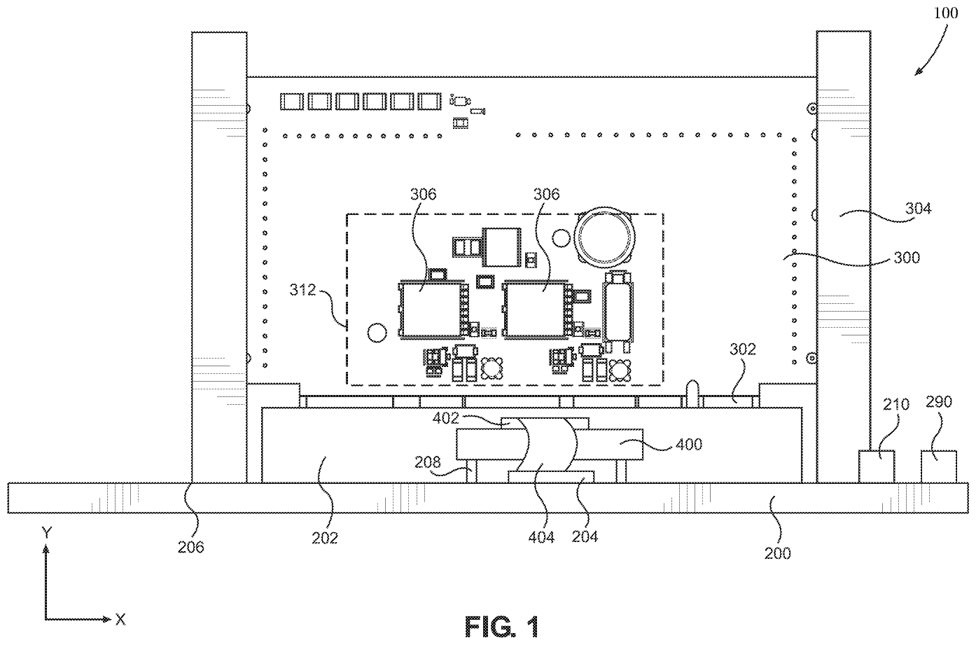

FIG. 1 illustrates a front view of a modular platform according to aspects of the disclosure.

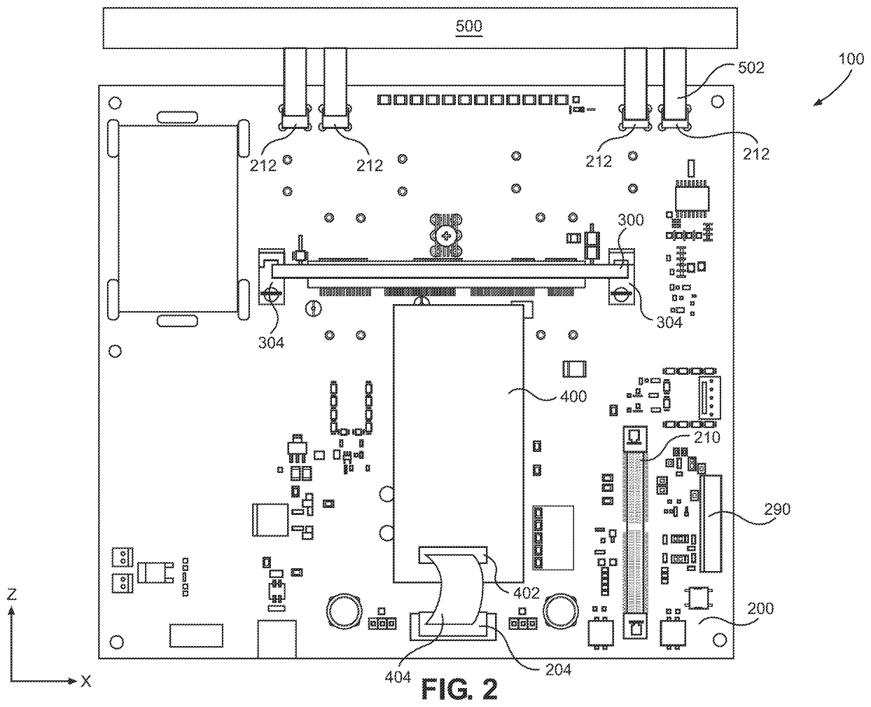

FIG. 2 illustrates a top view of a modular platform according to FIG. 1.

In particular, FIG. 1 and FIG. 2 illustrate a modular platform 100 having a mother board 200 and at least one daughter board 300. Further the at least one daughter board 300 may include at least one active device 306 as illustrated in FIG. 1. Moreover, the modular platform 100 and/or the mother board 200 may be configured to operate with a plurality of different implementations of the at least one daughter board 300. The plurality of different implementations of the at least one daughter board 300 having different configurations, types, and/or the like of the at least one active device 306 and/or the like.

Additionally, the modular platform 100 may include a secondary component 400. Moreover, the modular platform 100 and/or the mother board 200 may be configured to operate with a plurality of different types of implementations of the secondary component 400. The plurality of different types of the secondary component 400 having different configurations, types, and/or the like.

Further, the modular platform 100 may include a high-power power source 500 as illustrated in FIG. 2. Moreover, the modular platform 100 and/or the mother board 200 may be configured to operate with a plurality of different types of implementations of the high-power power source 500. The plurality of different types of the high-power power source 500 having different configurations, types, and/or the like.

Accordingly, the modular platform 100 may be configured for operation with multiple different device implementations of the at least one daughter board 300, the secondary component 400, the high-power power source 500, and/or the like.

The modular platform 100 may be configured as an evaluation platform configured for testing the various implementations of the at least one daughter board 300, various implementations of the secondary component 400, various implementations of the high-power power source 500, and/or the like. In this regard, the at least one daughter board 300 may include various implementations of the at least one active device 306 such as transistors, silicon carbide (SiC) metal-oxide-semiconductor field-effect transistors (MOSFETs), SiC diodes, SiC Schottky diodes, silicon (Si) MOSFETS, Si diodes, insulated-gate bipolar transistors (IGBTs), and/or the like; and the secondary component 400 may include various implementations of gate drive circuits, controllers, and/or the like.

The modular platform 100 may be configured such that the modular platform 100 may be broken down into modular pieces that may include the at least one daughter board 300, the secondary component 400, the high-power power source 500, and/or the like. The modular platform 100 may be configured to separate out various components such as the at least one daughter board 300, the secondary component 400, the high-power power source 500, and/or the like, such as the power switching devices, the gate driver, the control, a DC Bus, and/or the like making it easier to test components in different configurations. The modular platform 100 may allow users to very easily test the various implementations of the at least one active device 306 implemented in various implementations of the at least one daughter board 300, the secondary component 400, the high-power power source 500, and/or the like. The various implementations of the at least one daughter board 300 may include different implementations of transistors, diodes, and/or the like in different packages, different current ratings, and/or the like. Additionally, users can implement the modular platform 100 to work with a range of different associated devices that may be implemented by the mother board 200, the secondary component 400, the high-power power source 500, and/or the like, such as different gate drivers, different gate power supply options, different power supply options, different controllers, and/or the like.

The modular platform 100 may be implemented in a product to facilitate high-power density by placing the at least one active device 306 on or in the at least one daughter board 300 perpendicular to the mother board 200. In particular, the at least one active device 306 may be arranged on or in a surface of the at least one daughter board 300 in the Y-X plane as illustrated in FIG. 1 perpendicular to a surface of the mother board 200 in the Z-X plane illustrated in FIG. 2. The modular platform 100 may also be used to facilitate easy manufacturing and repair of applications, such as a power converter, and/or the like. The modular platform 100 may leverage economies of scale by building a common power card implementation of the at least one daughter board 300 that may be implemented by the mother board 200 and may be used in many applications.

The applications may include a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, electric vehicles (EVs), a converter, and/or the like.

The mother board 200 may include at least one mother board electrical connector 202 and the at least one daughter board 300 may include at least one daughter board electrical connector 302. The at least one mother board electrical connector 202 of the mother board 200 and the at least one daughter board electrical connector 302 of the at least one daughter board 300 may be configured to connect and exchange electrical signals, data, electrical power, and/or the like. Additionally, the mother board 200 may include a data connector 210 that may be configured to connect and exchange electrical signals, data, electrical power, and/or the like with a separate device, separate system, and/or the like; and/or the mother board 200 may include another data connector 290 that may be configured to connect and exchange electrical signals, data, electrical power, and/or the like with a man machine interface, a separate device, a separate system, and/or the like. In aspects, the another data connector 290 may be implemented as a customer/user accessible connector. In this regard, the another data connector 290 may be configured to provide sensor information, such as voltage sensor information, to the customer/user.

The secondary component 400 may include a secondary component electrical connector 402. Moreover, the mother board 200 may include a secondary component electrical connector 204. The secondary component electrical connector 204 of the mother board 200 and the secondary component electrical connector 402 of the secondary component 400 may be configured to connect and exchange electrical signals, data, electrical power, and/or the like. The secondary component electrical connector 204 and the secondary component electrical connector 402 may include an interconnect 404, such as a ribbon cable.

Additionally, the secondary component 400 may be configured to connect and exchange electrical signals, data, electrical power, and/or the like with the at least one daughter board 300. In aspects, the secondary component 400 may be configured to connect and exchange electrical signals, data, electrical power, and/or the like with the at least one daughter board 300 through a separate connector. In aspects, the secondary component 400 may be configured to connect and exchange electrical signals, data, electrical power, and/or the like with the at least one daughter board 300 through the secondary component electrical connector 204, the mother board 200, the secondary component electrical connector 402, and/or the like.

Additionally, the secondary component 400 may be configured to connect and exchange electrical signals, data, electrical power, and/or the like with the at least one active device 306. In aspects, the secondary component 400 may be configured to connect and exchange electrical signals, data, electrical power, and/or the like with the at least one active device 306 through a separate connector. In aspects, the secondary component 400 may be configured to connect and exchange electrical signals, data, electrical power, and/or the like with the at least one active device 306 through the secondary component electrical connector 204, the mother board 200, the secondary component electrical connector 402, the at least one daughter board 300, and/or the like.

The at least one daughter board 300 may additionally be connected to the mother board 200 with at least one support structure 304. In this regard, the at least one support structure 304 may extend in the Y axis from an upper surface 206 of the mother board 200. Additionally, the at least one support structure 304 may engage edges of the at least one daughter board 300 to support the at least one daughter board 300 above the mother board 200 as well as to fix the at least one daughter board 300 in relation to the mother board 200. Moreover, the at least one support structure 304 may arrange the at least one daughter board 300 such that the at least one daughter board electrical connector 302 of the at least one daughter board 300 engages the at least one mother board electrical connector 202 of the mother board 200. The at least one support structure 304 may include slots extending along the y-axis to receive edges of the mother board 200. The at least one support structure 304 may include a mechanical locking component to lock the at least one daughter board 300 to the at least one support structure 304.

The secondary component 400 may be arranged above the mother board 200 with a gap between a bottom surface of the secondary component 400 and the upper surface 206 of the mother board 200. In aspects, the mother board 200 and/or the secondary component 400 may include support structures 208 extending to the bottom surface of the secondary component 400 and from the upper surface 206 of the mother board 200. The support structures 208 may support the secondary component 400 in relation to the mother board 200. The secondary component 400 may be a gate driver, a gate driver circuit, a controller, a control board, and/or the like.

Additionally, the at least one daughter board 300 may include measurement circuitry 312. The measurement circuitry 312 may be configured to measure various electrical parameters as further described below related to the at least one active device 306. The measurement circuitry 312 may include one or more current sensors, one or more voltage sensors, one or more temperature sensors, and/or the like. In particular aspects, the measurement circuitry 312 may include one or more current sensors to measure current in the at least one active device 306 and/or the at least one daughter board 300, one or more voltage sensors to measure voltage in the at least one active device 306 and/or the at least one daughter board 300, one or more temperature sensors to measure temperature in the at least one active device 306 and/or the at least one daughter board 300, and/or the like. In one aspect, the one or more temperature sensors may be implemented as a thermistor arranged near the at least one active device 306 to measure temperature in the at least one active device 306. The measurement circuitry 312 may also or alternatively be implemented by the mother board 200, the secondary component 400, and/or the like.

In aspects, the mother board 200 may additionally implement the measurement circuitry 312 and may include one or more current sensors, one or more voltage sensors, one or more temperature sensors, and/or the like. Moreover, the measurement circuitry 312 implemented by the mother board 200 may gather electrical data collected by the measurement circuitry 312 and pass the electrical data to the data connector 210 and/or the another data connector 290 for use by a man machine interface, a separate device, a separate system, and/or the like. In aspects, the another data connector 290 may be implemented as a customer/user accessible connector. In this regard, the another data connector 290 may be configured to provide sensor information from the measurement circuitry 312 implemented by the mother board 200 to the customer/user.

With reference to FIG. 2, the mother board 200 of the modular platform 100 may include power connections 212. The power connections 212 may be configured to connect to the high-power power source 500 to provide power to the mother board 200, the at least one daughter board 300, the at least one active device 306, and/or the like. Moreover, the modular platform 100 and/or the mother board 200 may be configured to operate with a plurality of different types of implementations of the high-power power source 500. The plurality of different types of the high-power power source 500 having different configurations, types, and/or the like. The high-power power source 500 may include power source connections 502. The power source connections 502 may connect the high-power power source 500 to the power connections 212.

The mother board 200 may be configured to electrically deliver the power from the power connections 212 through the at least one mother board electrical connector 202 to the at least one daughter board electrical connector 302 and provide this power to the at least one daughter board 300. Thereafter, the at least one daughter board 300 may deliver the power to the at least one active device 306. The mother board 200 may be configured with interconnects to deliver the power from the power connections 212 to the at least one mother board electrical connector 202; and the at least one daughter board 300 may be configured with interconnects to deliver the power from the at least one daughter board electrical connector 302 to the at least one active device 306.

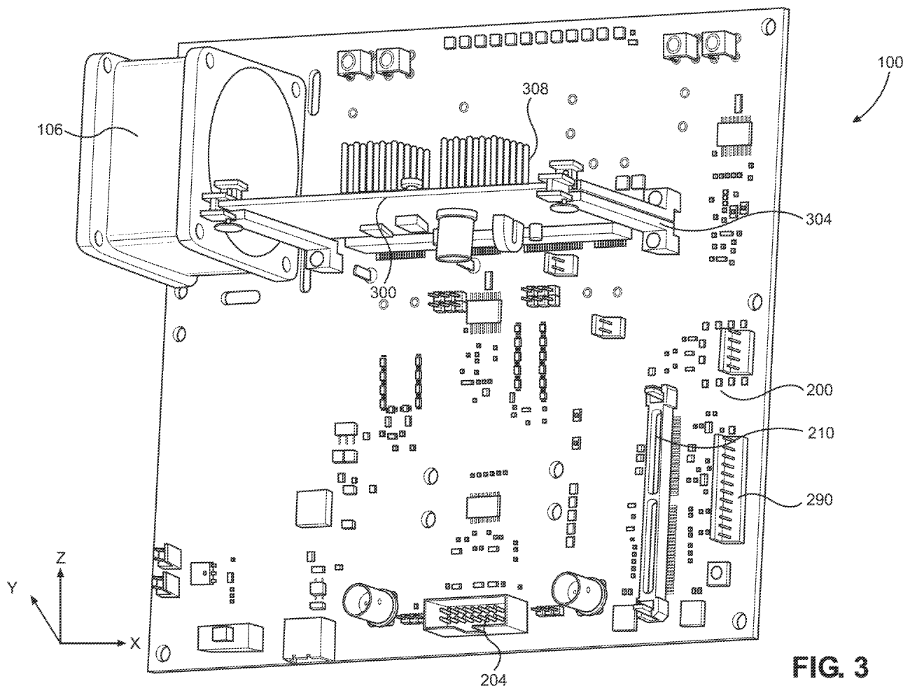

FIG. 3 illustrates a top perspective view of a modular platform according to FIG. 1.

In particular, FIG. 3 illustrates the modular platform 100 implementing the mother board 200 and the at least one daughter board 300 without illustrating the secondary component 400 and the high-power power source 500 for ease of understanding. As illustrated in FIG. 3, the modular platform 100 may further include a cooling component 106. The cooling component 106 may be a fan configured to convey air across the mother board 200 and in particular across the at least one daughter board 300. In this regard, the at least one daughter board 300 may be configured with cooling fins 308 located on a back surface of the at least one daughter board 300. Accordingly, the cooling component 106 may convey air across the cooling fins 308 of the at least one daughter board 300 to cool the at least one daughter board 300 and, in particular, cool the at least one active device 306 of the at least one daughter board 300.

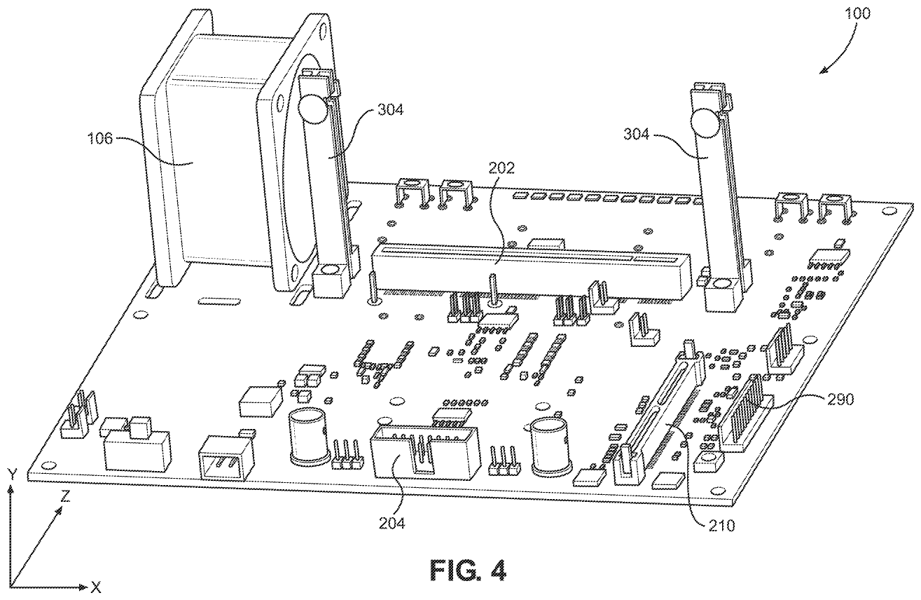

FIG. 4 illustrates a front perspective view of a modular platform according to FIG. 1.

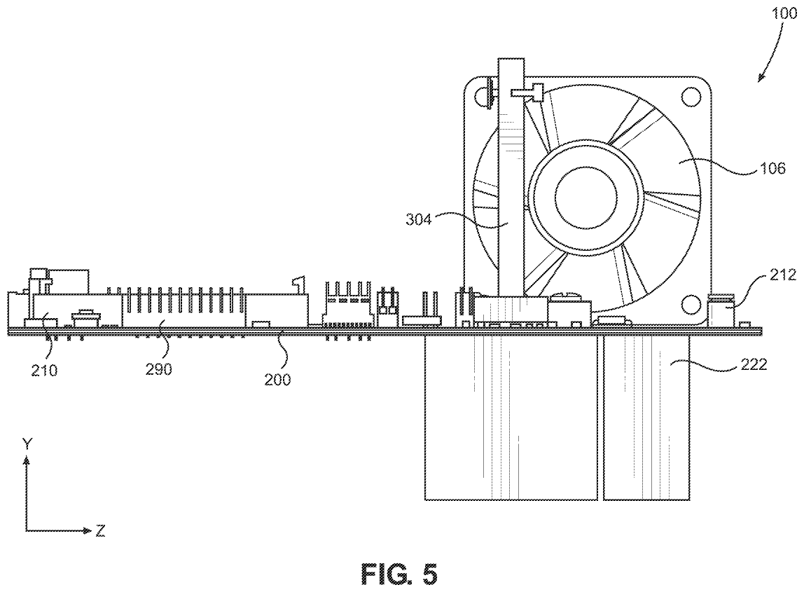

FIG. 5 illustrates a side view of a modular platform according to FIG. 1.

Referring to FIG. 4 and FIG. 5, these Figures illustrate the modular platform 100 implementing the mother board 200 without illustrating the at least one daughter board 300, the high-power power source 500, and the secondary component 400 for ease of understanding. Additionally, FIG. 5 illustrates that the mother board 200 of the modular platform 100 may further include at least one capacitor 222.

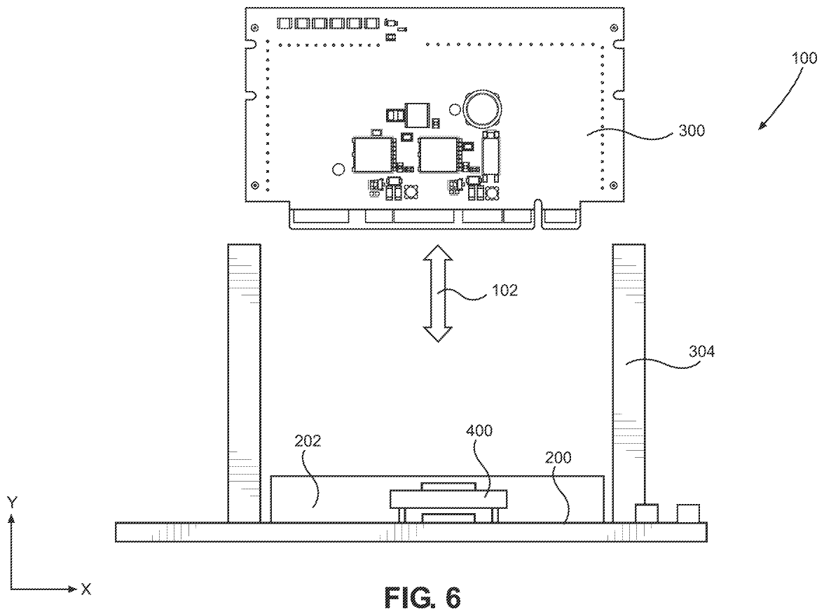

FIG. 6 illustrates another front view of a modular platform according to FIG. 1.

In particular, FIG. 6 illustrates that the modular platform 100 may be configured with the at least one support structure 304 to allow the at least one daughter board 300 to be removed from the mother board 200. In particular, the at least one support structure 304 may be configured to allow the at least one daughter board 300 to slide and move in the direction of arrow 102 to disconnect the at least one daughter board 300 and the at least one daughter board electrical connector 302 from the mother board 200 and the at least one mother board electrical connector 202. In this regard, the at least one support structure 304 may extend along the y-axis from the mother board 200; and moreover may be arranged on either side of the at least one mother board electrical connector 202. This configuration may allow the modular platform 100 to utilize a different implementation of the at least one daughter board 300. In particular, the modular platform 100 may be configured to couple different implementations of the at least one daughter board 300 with the mother board 200 easily by movement of the at least one daughter board 300 in the direction of arrow 102 as illustrated in FIG. 6. Thus, a first implementation of the at least one daughter board 300 may be removed from the modular platform 100 and a second different implementation of the at least one daughter board 300 may be inserted into the modular platform 100 for operation of the modular platform 100.

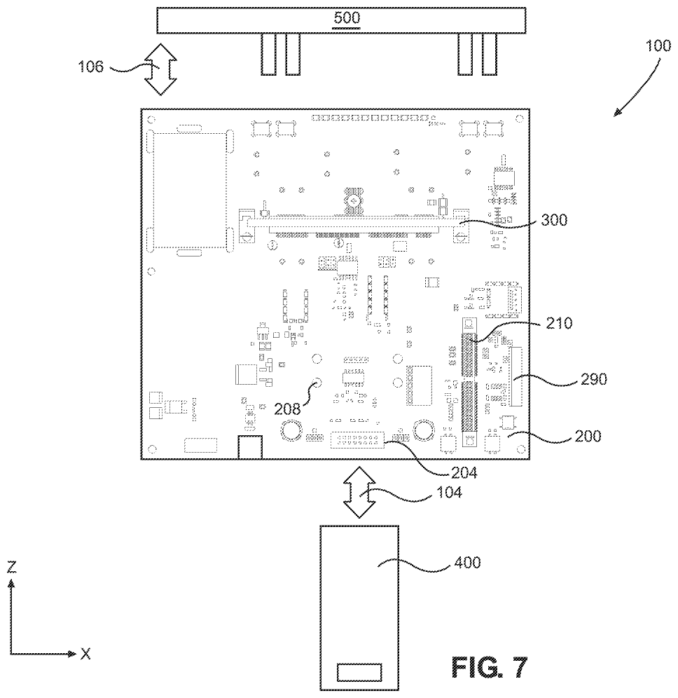

FIG. 7 illustrates a top view of a modular platform according to FIG. 1.

In particular, FIG. 7 illustrates that the modular platform 100 may be configured with the support structures 208 to allow the secondary component 400 to be removed from the mother board 200. In particular, the support structures 208 may be configured to allow the secondary component 400 to slide and move in the direction of arrow 104 to disconnect the secondary component 400 from the mother board 200. Accordingly, the secondary component electrical connector 402, the interconnect 404, the secondary component electrical connector 204, and/or the like may be disconnected and/or manipulated to disconnect the secondary component 400 from the mother board 200. This configuration may allow the modular platform 100 to utilize a different implementations of the secondary component 400. In particular, the modular platform 100 may be configured to couple different implementations of the secondary component 400 with the mother board 200 easily by movement of the secondary component 400 in the direction of arrow 104 as illustrated in FIG. 7. Thus, a first implementation of the secondary component 400 may be removed from the modular platform 100 and a second different implementation of the secondary component 400 may be attached to the modular platform 100 for operation of the modular platform 100.

Additionally, the modular platform 100 may be configured to utilize a different implementations of the high-power power source 500. In particular, the modular platform 100 may be configured to couple different implementations of the high-power power source 500 with the mother board 200 easily by movement of the secondary component 400 in the direction of arrow 106 as illustrated in FIG. 7. In particular, the power source connections 502 may be disconnected from the power connections 212 such that a different implementation of the high-power power source 500 may be connected to the modular platform 100 and in particular the power connections 212. Thus, a first implementation of the high-power power source 500 may be disconnected from the modular platform 100 and a second different implementation of the secondary component 400 may be connected to the modular platform 100 for operation of the modular platform 100.

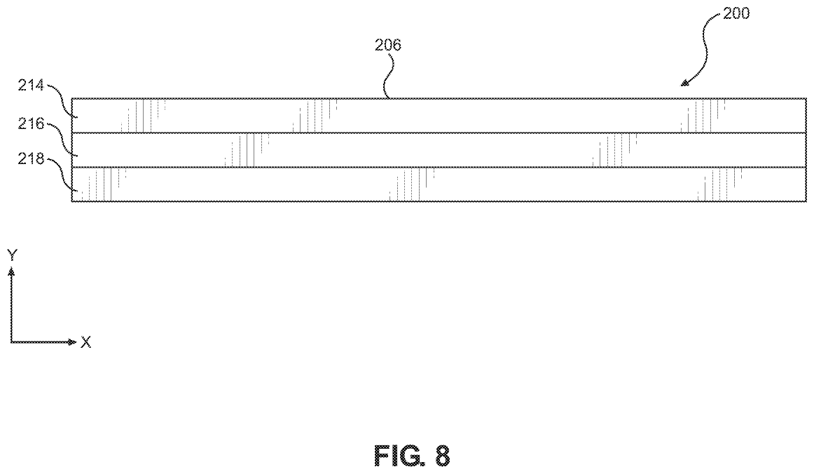

FIG. 8 illustrates a cross-sectional view of the mother board according to FIG. 1.

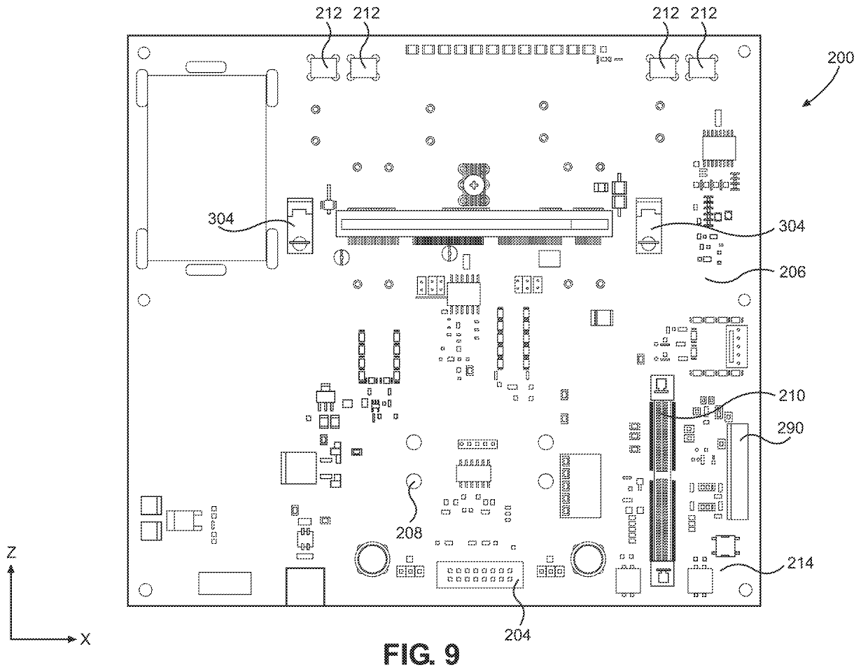

FIG. 9 illustrates a top view of the mother board according to FIG. 1.

In particular, FIG. 8 illustrates that the mother board 200 may include a multilayer structure having an upper layer 214, an intermediate layer 216, and a lower layer 218. Additionally, the mother board 200 may include additional layers between each of the upper layer 214, the intermediate layer 216, and the lower layer 218. In aspects, the upper layer 214 may include the upper surface 206. Additional layers are contemplated as well for the mother board 200.

With reference to FIG. 9, the upper surface 206 of the upper layer 214 may support one or more of the at least one mother board electrical connector 202, the secondary component electrical connector 204, the support structures 208, the data connector 210, the another data connector 290, the power connections 212, the at least one support structure 304, and/or the like. Additionally, one or more of the at least one mother board electrical connector 202, the secondary component electrical connector 204, the support structures 208, the data connector 210, the another data connector 290, the power connections 212, the at least one support structure 304, and/or the like may include fasteners or other structure extending through one or more of the upper layer 214, the intermediate layer 216, and the lower layer 218 of the mother board 200. Moreover, one or more of the at least one mother board electrical connector 202, the secondary component electrical connector 204, the support structures 208, the data connector 210, the another data connector 290, the power connections 212, and/or the like may include electrical connections extending through the upper layer 214 and further extending to one or more of the intermediate layer 216 and the lower layer 218 of the mother board 200.

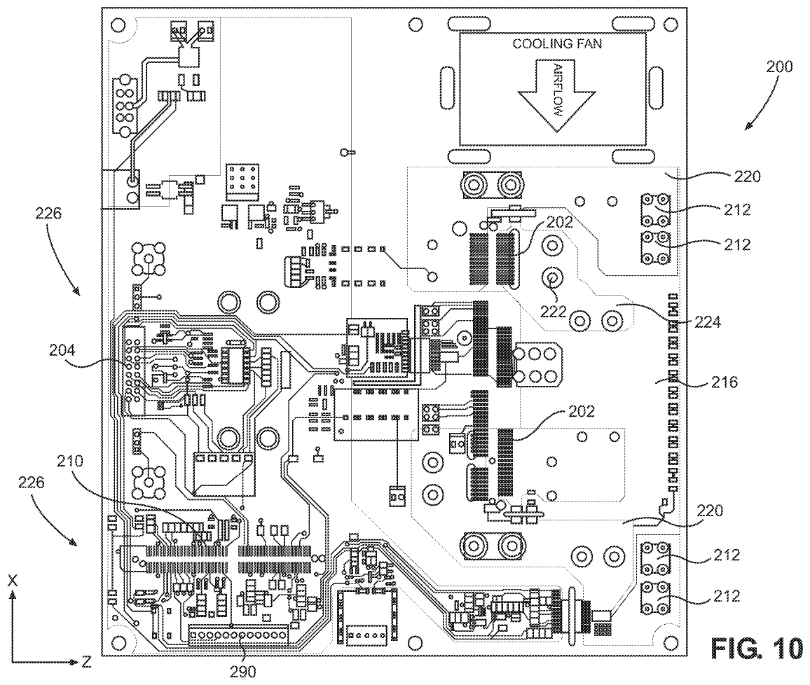

FIG. 10 illustrates a view of the intermediate layer according to FIG. 1.

In particular, FIG. 10 illustrates an exemplary implementation of the intermediate layer 216 of the mother board 200. In this regard, one or more of the at least one mother board electrical connector 202, the secondary component electrical connector 204, the support structures 208, the data connector 210, the another data connector 290, the power connections 212, and/or the like may include electrical connections to and/or across the intermediate layer 216 of the mother board 200.

In aspects, the power connections 212 may include portions that extend to the intermediate layer 216 to an electrical connection 220. The electrical connection 220 may extend from the connections of the power connections 212 to the at least one mother board electrical connector 202. In aspects, the electrical connection 220 may be implemented with a wide path extending from the power connections 212 to the at least one mother board electrical connector 202. In this regard, a wide path as utilized herein refers to an electrical connection that is wider, parallel to the X-Z plane illustrated in FIG. 10, than it is thick, perpendicular to the X-Z plane illustrated in FIG. 10. Additionally, the at least one capacitor 222 may include electrical connections that may extend to the intermediate layer 216 and may connect to an electrical connection 224. The electrical connection 224 may extend from the connections to the at least one capacitor 222 to the at least one mother board electrical connector 202. In aspects, the electrical connection 224 may be implemented with a wide path as defined herein extending from the at least one capacitor 222 to the at least one mother board electrical connector 202. Additionally, the electrical connection 224 may be arranged parallel to the electrical connection 220. Accordingly, the combination of the wide path implementations of the electrical connection 220 and the electrical connection 224 as well as the parallel configuration of the electrical connection 220 and the electrical connection 224 may reduce inductance between the at least one mother board electrical connector 202 and the at least one capacitor 222 and the at least one mother board electrical connector 202 and the power connections 212.

Additionally, the secondary component electrical connector 204, the another data connector 290, and/or the data connector 210 may include electrical connections that extend to the intermediate layer 216. Additionally, the intermediate layer 216 may include electrical connections 226 that may extend from the electrical connections of the secondary component electrical connector 204 to the electrical connections of the at least one mother board electrical connector 202; other implementations of the electrical connections 226 may extend from the electrical connections of the data connector 210 and/or the another data connector 290 to the electrical connections of the at least one mother board electrical connector 202; and other implementations of the electrical connections 226 may extend from the electrical connections of the data connector 210 and/or the another data connector 290 to the electrical connections of secondary component electrical connector 204.

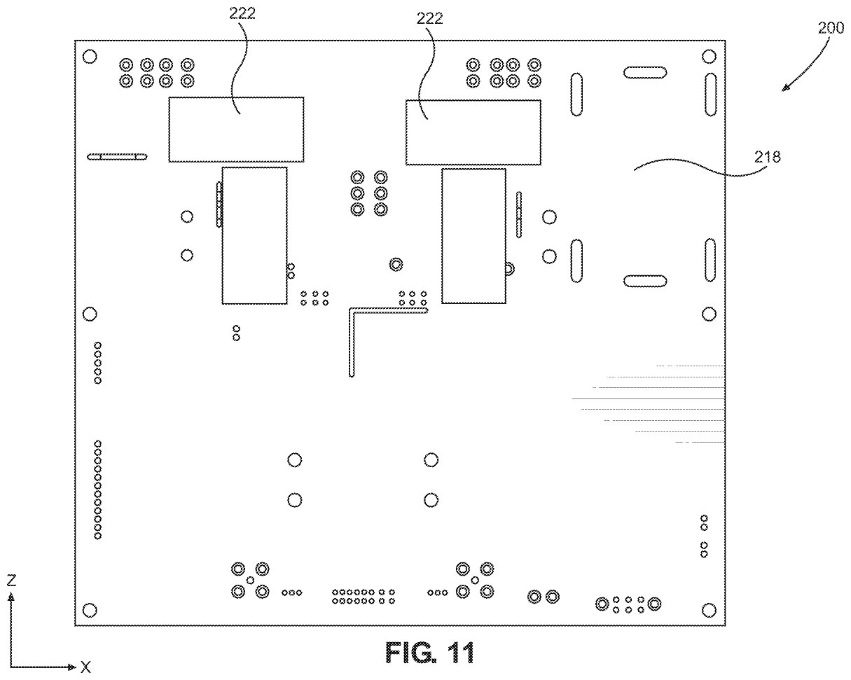

FIG. 11 illustrates a bottom view of the lower layer 218 according to FIG. 1.

As illustrated in FIG. 11, the at least one capacitor 222 may extend from the lower layer 218 and may be connected to the intermediate layer 216 as illustrated in FIG. 10. Additionally, one or more of the at least one mother board electrical connector 202, the secondary component electrical connector 204, the support structures 208, the data connector 210, the another data connector 290, the power connections 212, the at least one support structure 304, and/or the like may include connections that extend to the lower layer 218.

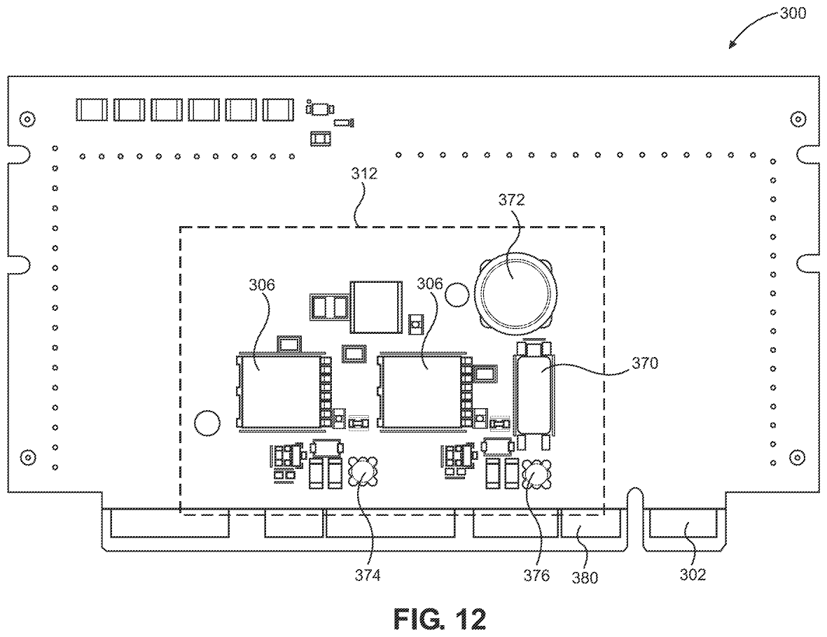

FIG. 12 illustrates a front view of an exemplary implementation of the at least one daughter board according to aspects of the disclosure.

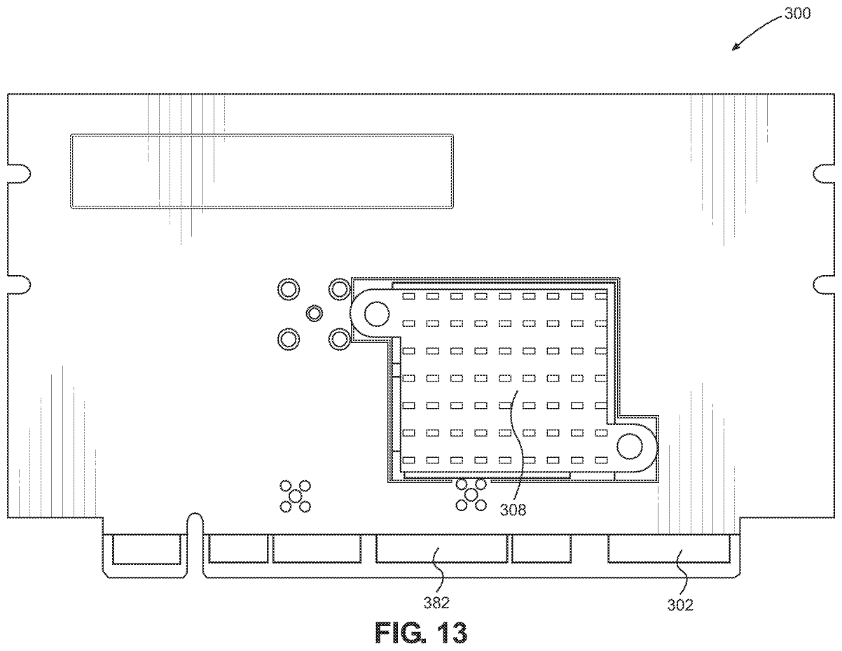

FIG. 13 illustrates a back view of an exemplary implementation of the at least one daughter board according to aspects of the disclosure.

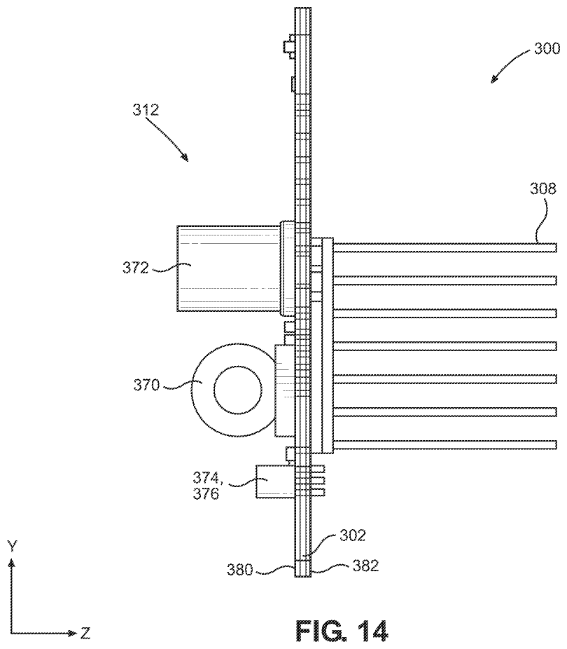

FIG. 14 illustrates a side view of an exemplary implementation of the at least one daughter board according to aspects of the disclosure.

In particular, FIG. 12 illustrates the at least one daughter board 300 implementing the at least one active device 306 as transistors. Additionally, the at least one daughter board 300 may include the measurement circuitry 312 arranged adjacent the at least one active device 306. As illustrated in FIG. 12, the at least one daughter board electrical connector 302 may include surfaces 380 on a front side of the at least one daughter board 300 for delivering power to and from the at least one active device 306 and delivering data and signals to and from the measurement circuitry 312, the at least one active device 306, and/or the like.

As illustrated in FIG. 13, the at least one daughter board electrical connector 302 may include surfaces 382 on a back side of the at least one daughter board 300 for delivering power to and from the at least one active device 306 and delivering data and signals to and from the measurement circuitry 312 and the at least one active device 306. In aspects, the at least one daughter board 300 may be a multilayered structure having electrical connection portions to the at least one daughter board electrical connector 302, the surfaces 382, the surfaces 380, the at least one active device 306, the measurement circuitry 312, and/or the like. Accordingly, as illustrated in FIG. 14, the at least one daughter board electrical connector 302 may have multiple connection portions on the front of the at least one daughter board 300 implemented by the surfaces 380 and on the back of the at least one daughter board 300 implemented by the surfaces 382.

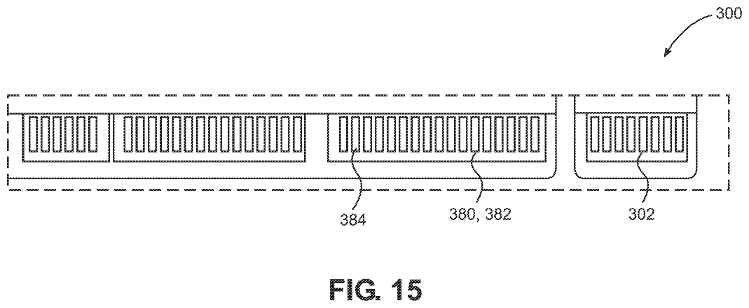

FIG. 15 illustrates a partial front view of an exemplary implementation of the at least one daughter board according to FIG. 12.

In particular, FIG. 15 illustrates the details of the at least one daughter board electrical connector 302 of the at least one daughter board 300 including the surfaces 380 or the surfaces 382. More specifically, the surfaces 380 or the surfaces 382 may include a plurality of contact portions 384. The plurality contact portions 384 being part of the at least one daughter board electrical connector 302 and may be arranged on one or both of the surfaces 380 and the surfaces 382. The plurality of contact portions 384 may have corresponding contact portions on the at least one mother board electrical connector 202 of the mother board 200. The plurality of contact portions 384 may each provide transfer of power, electrical signals, data, electrical power, and/or the like.

In aspects, a plurality of the plurality of contact portions 384 may provide transfer of power between the at least one active device 306 and the power connections 212. Moreover, a plurality of the plurality of contact portions 384 may be implemented by the surfaces 380 to provide transfer of power between the at least one active device 306 and the power connections 212; and a plurality of the plurality of contact portions 384 may be implemented by the surfaces 382 to provide transfer of power between the at least one active device 306 and the power connections 212. In this regard, these implementations of the surfaces 382 may be provided on opposing sides of the at least one daughter board 300 and/or the at least one daughter board electrical connector 302. This configuration may reduce inductance generated by the power being transferred between the at least one active device 306 and the power connections 212.

In aspects, a plurality of the plurality of contact portions 384 may provide transfer electrical signals, data, electrical power, and/or the like between the measurement circuitry 312 and the mother board 200, the data connector 210, the another data connector 290, the secondary component 400, and/or like. In this regard, the measurement circuitry 312 may measure various voltages of the at least one active device 306. For example, the measurement circuitry 312 may measure a gate voltage, a drain voltage, a source voltage, an upper gate source voltage, a lower gate source voltage, and/or the like. Additionally or alternatively, the measurement circuitry 312 may measure various temperatures on the at least one active device 306, the at least one daughter board 300, and/or the like. Additionally or alternatively, the measurement circuitry 312 may measure various currents through the at least one active device 306, the at least one daughter board 300, and/or the like including a source current, a drain current, and/or the like.

In aspects, referring back to FIG. 12 and FIG. 14 the measurement circuitry 312 may include at least one current sensor 370 arranged on the at least one daughter board 300 to measure a current associated with the at least one active device 306 and/or the at least one daughter board 300. In aspects, the at least one current sensor 370 may be implemented as a surface mount device current sensor configured to detect high frequency switching current of the at least one active device 306.

In aspects, the measurement circuitry 312 may include at least one voltage sensor 372 arranged on the at least one daughter board 300 to measure a lower drain source voltage of the at least one active device 306. In aspects, the measurement circuitry 312 may include at least one voltage sensor 374 arranged on the at least one daughter board 300 to measure an upper gate source voltage of the at least one active device 306. In aspects, the measurement circuitry 312 may include at least one voltage sensor 376 arranged on the at least one daughter board 300 to measure an upper gate source voltage of the at least one active device 306.

In aspects, the measurement circuitry 312 may measure and/or the plurality of contact portions 384 may transfer Miller Clamp Gate Signals, High Side Gate Signals, Miller Clamp Gate Signals, Miller Clamp VSS Signals, High Side Gate Signals, High Side Gate Signals, High Side Silicon-Controlled Rectifier (SCR) Signals, High Side Silicon-Controlled Rectifier (SCR) Signals, High Side Gate Sense (SNS) Signals, High Side Silicon-Controlled Rectifier (SCR) Sense (SNS) Signals, a first temperature signal, a second temperature signal, Miller Clamp Gate Signals, Miller Clamp Vss Signals, Low Side Gate Signals, Low Side Silicon-Controlled Rectifier (SCR) Signals, Low Side Silicon-Controlled Rectifier (SCR) Signals, Low Side Gate Sense (SNS) Signals, Low Side Silicon-Controlled Rectifier (SCR) Sense (SNS) Signals, Current Sense (SNS)+ Signals, Current Sense (SNS)− Signals, and/or the like.

In other aspects, the at least one daughter board 300 may be implemented with parallel implementations of the at least one active device 306. This may be beneficial for higher power implementations. Additionally, the at least one daughter board 300 may be implemented with other devices such as power modules.

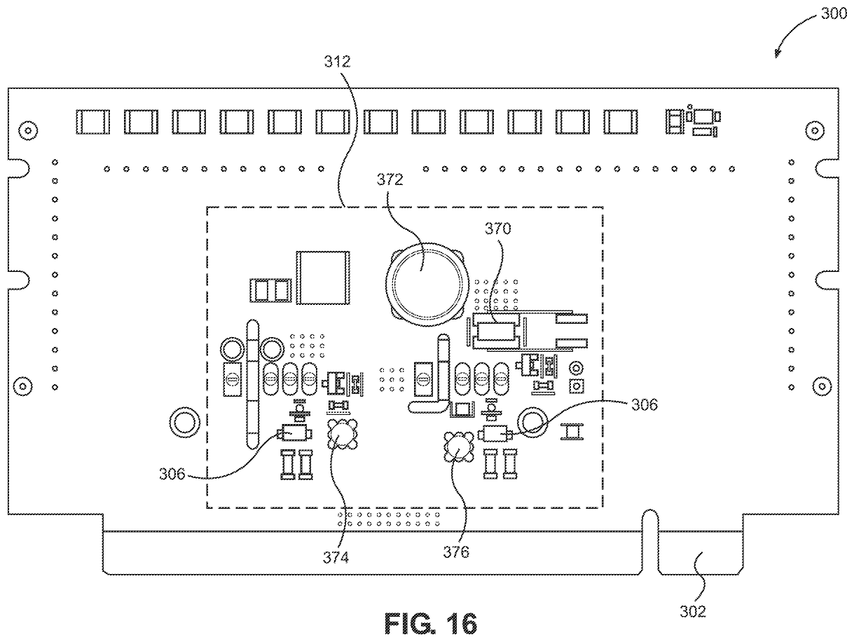

FIG. 16 illustrates a front view of another exemplary implementation of the at least one daughter board according to aspects of the disclosure.

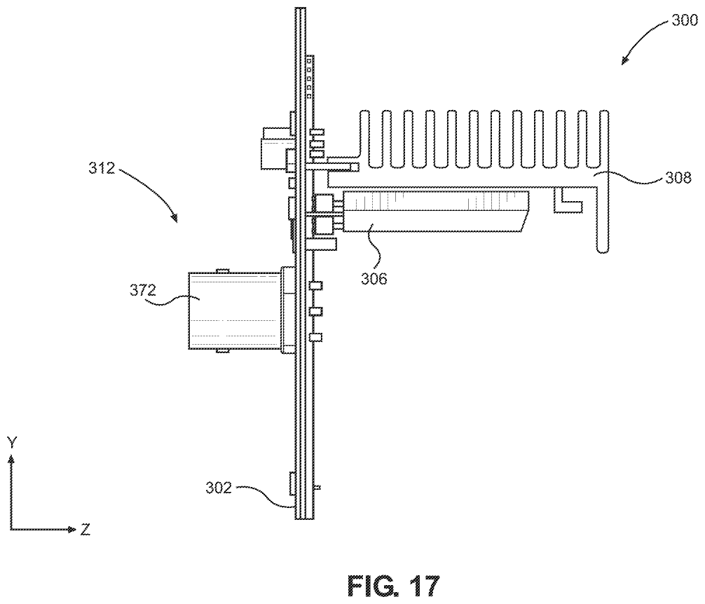

FIG. 17 illustrates a side view of an exemplary implementation of the at least one daughter board according to aspects of the disclosure.

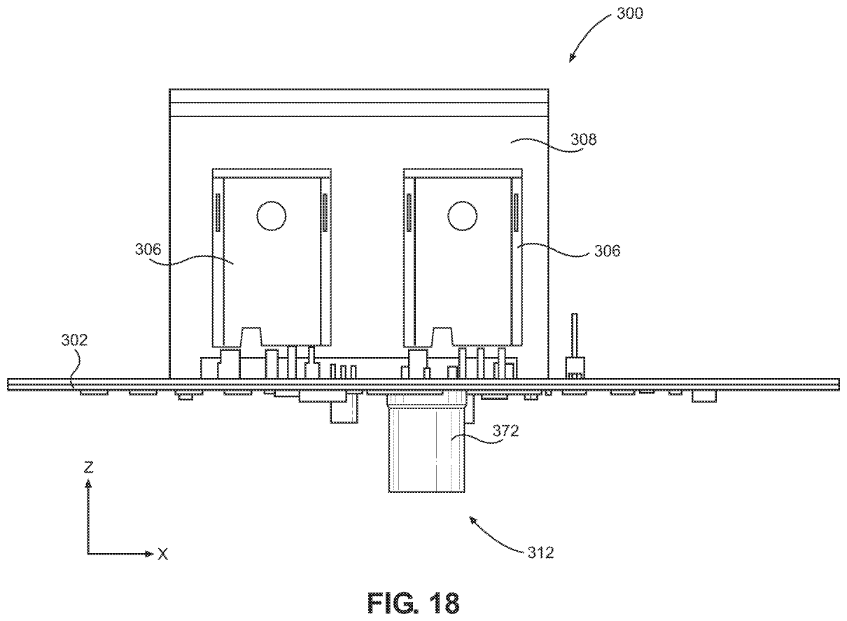

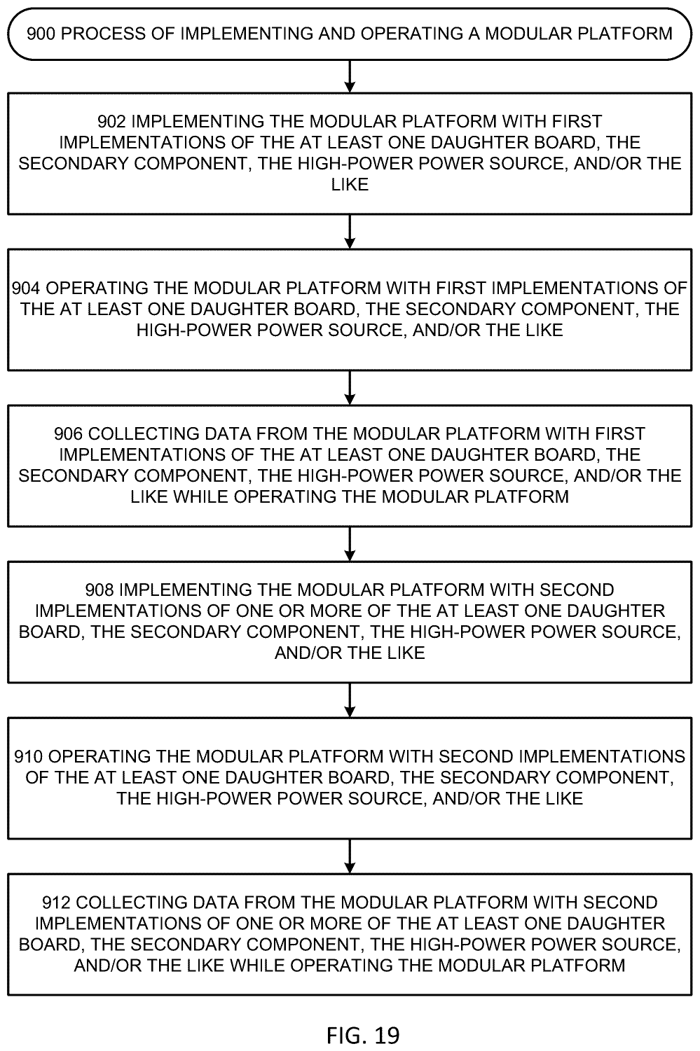

FIG. 18 illustrates a bottom view of an exemplary implementation of the at least one daughter board according to aspects of the disclosure.

In particular, FIG. 16, FIG. 17, and FIG. 18 illustrate implementation of the at least one daughter board 300 with the at least one active device 306 implemented as one or more power modules. Moreover, the cooling fins 308 may be attached to a surface of the at least one active device 306 as illustrated in FIG. 17.

Additionally, the modular platform 100, the at least one daughter board 300, and/or the like may be further implemented with various typologies, such as, a 3-phase inverter, a totem pole power factor correction (PFC), half-bridge, full-bridge DC/DC converter, resonant converters, e.g., LLC and CLLC, and/or the like.

The modular platform 100, the mother board 200, the at least one daughter board 300, the secondary component 400, a separate device, and/or the like may be implemented in part as a testing device and/or may include one or more of a processor, a memory, a display, a power supply, a read-only memory, an input device, an input/output device, an analog-to-digital converter, a digital to analog converter, a clock, one or more sensors, a power source, and/or the like. The processor may be configured to process at least in part test functions, provide other test services, and/or the like.

The power source may be configured as a highly stable DC power source, a constant current source, a constant voltage source, a variable current source, a variable voltage source, and/or the like. In one aspect, the testing device in conjunction with the power source may include sweep capabilities. The sweep capabilities may be configured to test the at least one active device 306 under a range of conditions with different sources, different voltages, different currents, different time periods, different delays, and/or the like. The measurement circuitry 312 may measure various device characteristics of the at least one active device 306. Moreover, the measurement circuitry 312 may measure various device characteristics during a sweeping function.

The testing device may implement instrument integration, communication, test protocols, test time, and/or the like by utilizing an on-board script processor. The testing device may allow user-defined on-board script execution for controlling test sequencing, test flow, decision making, instrument autonomy, and/or the like. The testing device may include contact check functionality to verify good connections to the at least one daughter board 300 and/or the at least one active device 306 under test before the test begins.

In one aspect, a software application may be executed by the processor and may be configured to interact with the measurement circuitry 312 and/or the like as described herein. In particular, the measurement circuitry 312 may provide signals to the modular platform 100, the processor, the at least one daughter board 300, the mother board 200, and/or the like.

The testing device may implement a testing protocol. The testing protocol may determine particular voltage levels, current amounts, time periods, and the like for the delivery to the at least one daughter board 300, the at least one active device 306, and/or the like. The testing device may be configured to utilize outputs from the measurement circuitry 312 to adjust the current, voltage, and/or the like provided by power source.

In particular aspects, the modular platform 100 may be configured to implement first implementations of the at least one daughter board 300, the secondary component 400, the high-power power source 500, and/or the like. Thereafter, the modular platform 100 may be configured to operate with first implementations of the at least one daughter board 300, the secondary component 400, the high-power power source 500, and/or the like. Furthermore, the modular platform 100 may be configured to collect data from the at least one active device 306 with the measurement circuitry 312 of the modular platform 100 with the first implementations of the at least one daughter board 300, the secondary component 400, the high-power power source 500, and/or the like while operating the modular platform 100.

Additionally, the modular platform 100 may be configured to implement second implementations of one or more of the at least one daughter board 300, the secondary component 400, the high-power power source 500, and/or the like. Furthermore, the modular platform 100 may be configured to operate the modular platform 100 with the second implementations of the at least one daughter board 300, the secondary component 400, the high-power power source 500, and/or the like. Additionally, the modular platform 100 may be configured to collect data from the at least one active device 306 with the measurement circuitry 312 of the modular platform 100 with the second implementations of the at least one daughter board 300, the secondary component 400, the high-power power source 500, and/or the like while operating the modular platform 100. Finally, the modular platform 100 may be configured to output the collected data to a man machine interface, the testing device, a computer system, and/or the like.

The one or more interconnects or electrical connections described herein may utilize traces, ball bonding, wedge bonding, compliant bonding, ribbon bonding, metal clip attach, and/or the like. The interconnects or electrical connections described herein may be include various metal materials including one or more of aluminum, copper, silver, gold, and/or the like. The interconnects or electrical connections may connect to a plurality of interconnect pads of components of the modular platform 100 by an adhesive, soldering, sintering, eutectic bonding, thermal compression bonding, ultrasonic bonding/welding, a clip component, and/or the like as described herein.

FIG. 18 illustrates a process of implementing and operating the modular platform according to aspects of the disclosure.

In particular, FIG. 18 illustrates a process of implementing and operating a modular platform 900. In particular, the process of implementing and operating the modular platform 900 may include a process of implementing and operating the modular platform 100 including the mother board 200, the at least one daughter board 300, the secondary component 400, the high-power power source 500, and/or the like as described herein.

It should be noted that the aspects of the process of implementing and operating the modular platform 900 may be performed in a different order consistent with the aspects described herein. Additionally, it should be noted that portions of the process of implementing and operating the modular platform 900 may be performed in a different order consistent with the aspects described herein. Moreover, the process of implementing and operating the modular platform 900 may be modified to have more or fewer processes consistent with the various aspects disclosed herein. Additionally, the process of implementing and operating the modular platform 900 may include any other aspects of the disclosure described herein.

The process of implementing and operating a modular platform 900 may include implementing the modular platform with first implementations of the at least one daughter board, the secondary component, the high-power power source, and/or the like 902. In particular, the implementing the modular platform with first implementations of the at least one daughter board, the secondary component, the high-power power source, and/or the like 902 may include implementing the modular platform 100 with first implementations of the at least one daughter board 300, the secondary component 400, the high-power power source 500, and/or the like as described herein.

Thereafter, the process of implementing and operating a modular platform 900 may include operating the modular platform with first implementations of the at least one daughter board, the secondary component, the high-power power source, and/or the like 904. In particular, the operating the modular platform with first implementations of the at least one daughter board, the secondary component, the high-power power source, and/or the like may include operating the modular platform 100 with first implementations of the at least one daughter board 300, the secondary component 400, the high-power power source 500, and/or the like as described herein.

Further, the process of implementing and operating a modular platform 900 may include collecting data from the modular platform with first implementations of the at least one daughter board, the secondary component, the high-power power source, and/or the like while operating the modular platform 906. In particular, the collecting data from the modular platform with first implementations of the at least one daughter board, the secondary component, the high-power power source, and/or the like while operating the modular platform 906 may include collecting data from the at least one active device 306 with the measurement circuitry 312 of the modular platform 100 with first implementations of the at least one daughter board 300, the secondary component 400, the high-power power source 500, and/or the like while operating the modular platform 100.

The process of implementing and operating a modular platform 900 may include implementing the modular platform with second implementations of one or more of the at least one daughter board, the secondary component, the high-power power source, and/or the like 908. In particular, the implementing the modular platform with second implementations of one or more of the at least one daughter board, the secondary component, the high-power power source, and/or the like 908 may include implementing the modular platform 100 with second implementations of one or more of the at least one daughter board 300, the secondary component 400, the high-power power source 500, and/or the like as described herein.

Thereafter, the process of implementing and operating a modular platform 900 may include operating the modular platform with second implementations of the at least one daughter board, the secondary component, the high-power power source, and/or the like 910. In particular, the operating the modular platform with second implementations of the at least one daughter board, the secondary component, the high-power power source, and/or the like 910 may include operating the modular platform 100 with second implementations of the at least one daughter board 300, the secondary component 400, the high-power power source 500, and/or the like as described herein.

Further, the process of implementing and operating a modular platform 900 may include collecting data from the modular platform with second implementations of one or more of the at least one daughter board, the secondary component, the high-power power source, and/or the like while operating the modular platform 912. In particular, the collecting data from the modular platform with second implementations of one or more the at least one daughter board, the secondary component, the high-power power source, and/or the like while operating the modular platform 912 may include collecting data from the at least one active device 306 with the measurement circuitry 312 of the modular platform 100 with second implementations of the at least one daughter board 300, the secondary component 400, the high-power power source 500, and/or the like while operating the modular platform 100 as described herein. Thereafter, the process of implementing and operating a modular platform 900 may be repeated for additional implementations of the at least one daughter board 300, the secondary component 400, the high-power power source 500, and/or the like.

The process of implementing and operating a modular platform 900 may further include outputting the collected data to a man machine interface, the testing device, a computer system, and/or the like. In one aspect, the operating parameters may be analyzed by a computer system. In one aspect, the computer system may analyze the operating parameters including data from the measurement circuitry 312 to generate an output. In one aspect, the output may be provided to a man machine interface. In one aspect, the man machine interface may include one or more of a display, a print out, an analysis file, and the like.

The disclosed method and system may be utilized for any type of semiconductor device, transistor, power device, and/or power module. In this regard, the transistor types may include but are not limited to a MEtal Semiconductor Field-Effect Transistor (MESFET), a Metal Oxide Field Effect Transistor (MOSFET), a Junction Field Effect Transistor (JFET), a Bipolar Junction Transistor (BJT), an Insulated Gate Bipolar Transistor (IGBT), a high-electron-mobility transistor (HEMT), and the like. The term power device may refer to various forms of transistors and diodes designed for high voltages and currents. The transistors may be controllable switches allowing for unidirectional or bidirectional current flow (depending on device type) while the diodes may allow for current flow in one direction and may not controllable. The power module may implement a plurality of power devices that range in structure and purpose. The power devices may include Wide Band Gap (WBG) semiconductors, including Gallium Nitride (GaN), Silicon Carbide (SiC), and the like, and offer numerous advantages over conventional Silicon (Si) as a material for the power devices. Nevertheless, various aspects of the disclosure may utilize Si type power devices and achieve a number of the benefits described herein.

The application may be a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, and electric vehicles (EVs), a converter, and the like.

Accordingly, the disclosure has provided and described methods and systems configured for implementing different components and devices.

### Examples

The following are a number of nonlimiting EXAMPLES of aspects of the disclosure. One EXAMPLE includes: EXAMPLE 1. A modular platform includes: a mother board; at least one daughter board; the at least one daughter board includes at least one active device; and the at least one daughter board includes measurement circuitry, where the mother board is configured to operate with a plurality of different implementations of the at least one daughter board; and where the plurality of different implementations of the at least one daughter board includes different configurations and/or types of the at least one active device.

The above-noted EXAMPLE may further include any one or a combination of more than one of the following EXAMPLES: 2. The modular platform according to any EXAMPLE herein where: the measurement circuitry is configured to measure electrical parameters of the at least one active device; and the measurement circuitry includes one or more current sensors, one or more voltage sensors, and/or one or more temperature sensors. 3. The modular platform according to any EXAMPLE herein where the at least one active device includes at least one transistor, diode, and/or power module. 4. The modular platform according to any EXAMPLE herein where: the mother board includes at least one mother board electrical connector and the at least one daughter board includes at least one daughter board electrical connector; and the at least one mother board electrical connector and the at least one daughter board electrical connector are configured to connect and exchange electrical signals, data, and/or electrical power. 5. The modular platform according to any EXAMPLE herein where: the mother board includes power connections configured to connect to a high-power power source; and the mother board includes connections between the power connections and the at least one mother board electrical connector. 6. The modular platform according to any EXAMPLE herein includes: a secondary component that includes a gate driver circuit, a controller, and/or a control board, where the mother board is configured to operate with a plurality of different types of implementations of the secondary component. 7. The modular platform according to any EXAMPLE herein where: the secondary component includes a secondary component electrical connector and the mother board includes a secondary component electrical connector; and the secondary component electrical connector of the mother board and the secondary component electrical connector of the secondary component are configured to connect and exchange electrical signals, data, and/or electrical power. 8. The modular platform according to any EXAMPLE herein includes: a secondary component that includes a gate driver circuit, a controller, and/or a control board, where the secondary component and the at least one daughter board are configured to connect and exchange electrical signals, data, and/or electrical power. 9. The modular platform according to any EXAMPLE herein where the mother board is configured to operate with a plurality of different types of implementations of a high-power power source. 10. The modular platform according to any EXAMPLE herein where the mother board includes a data connector that is configured to connect and exchange electrical signals and/or data with a separate device. 11. The modular platform according to any EXAMPLE herein includes at least one support structure configured to hold the at least one daughter board and the at least one support structure further configured to allow the at least one daughter board to be removed from the mother board. 12. The modular platform according to any EXAMPLE herein includes: a secondary component that includes a gate driver circuit, a controller, and/or a control board, where the mother board is configured to operate with a plurality of different types of implementations of the secondary component; and where the mother board is configured to operate with a plurality of different types of implementations of a high-power power source. 13. An evaluation platform includes the modular platform according to any EXAMPLE herein. 14. An application system includes the modular platform according to any EXAMPLE herein, where the application system includes one of a power system, a motor system, an automotive motor system, a charging system, an automotive charging system, a vehicle system, an industrial motor drive system, an embedded motor drive system, an uninterruptible power supply system, an AC-DC power supply system, a welder power supply system, a military system, an inverter system, an inverter for a wind turbine system, a solar power panel system, tidal power plant system, an electric vehicle (EVs) system, and/or a converter.

One EXAMPLE includes: EXAMPLE 15. A method of implementing a modular platform includes: providing a mother board; providing at least one daughter board; configuring the at least one daughter board with at least one active device; and configuring the at least one daughter board with measurement circuitry; and configuring the mother board to operate with a plurality of different implementations of the at least one daughter board, where the plurality of different implementations of the at least one daughter board includes different configurations and/or types of the at least one active device.

The above-noted EXAMPLE may further include any one or a combination of more than one of the following EXAMPLES: 16. The method of implementing the modular platform according to any EXAMPLE herein includes: measuring electrical parameters of the at least one active device with the measurement circuitry, where the measurement circuitry includes one or more current sensors, one or more voltage sensors, and/or one or more temperature sensors. 17. The method of implementing the modular platform according to any EXAMPLE herein where the at least one active device includes at least one transistor, diode, and/or power module. 18. The method of implementing the modular platform according to any EXAMPLE herein includes: configuring the mother board with at least one mother board electrical connector; configuring the at least one daughter board with at least one daughter board electrical connector; and connecting the at least one mother board electrical connector and the at least one daughter board electrical connector to exchange electrical signals, data, and/or electrical power. 19. The method of implementing the modular platform according to any EXAMPLE herein includes: configuring the mother board with power connections to connect to a high-power power source; and configuring connections in the mother board between the power connections and the at least one mother board electrical connector. 20. The method of implementing the modular platform according to any EXAMPLE herein includes: providing a secondary component that includes a gate driver circuit, a controller, and/or a control board; and configuring the mother board to operate with a plurality of different types of implementations of the secondary component. 21. The method of implementing the modular platform according to any EXAMPLE herein includes: providing a secondary component that includes a gate driver circuit, a controller, and/or a control board; and where the secondary component and the at least one daughter board are configured to connect and exchange electrical signals, data, and/or electrical power. 22. The method of implementing the modular platform according to any EXAMPLE herein where the mother board is configured to operate with a plurality of different types of implementations of a high-power power source. 23. The method of implementing the modular platform according to any EXAMPLE herein includes configuring the mother board with a data connector to connect and exchange electrical signals and/or data with a separate device. 24. The method of implementing the modular platform according to any EXAMPLE herein includes configuring at least one support structure configured to hold the at least one daughter board and the at least one support structure further configured to allow the at least one daughter board to be removed from the mother board. 25. The method of implementing the modular platform according to any EXAMPLE herein includes: implementing a secondary component that includes a gate driver circuit, a controller, and/or a control board, where the mother board is configured to operate with a plurality of different types of implementations of the secondary component; and where the mother board is configured to operate with a plurality of different types of implementations of a high-power power source. 26. The method of implementing the modular platform according to any EXAMPLE herein includes: configuring the secondary component with a secondary component electrical connector; configuring the mother board with a secondary component electrical connector; and connecting the secondary component electrical connector of the mother board and the secondary component electrical connector of the secondary component to and exchange electrical signals, data, and/or electrical power.

One EXAMPLE includes: EXAMPLE 27. An apparatus includes: a mother board; at least one daughter board; and the at least one daughter board includes at least one active device, where the apparatus is configured to facilitate high-power density by placing the at least one active device on or in the at least one daughter board such that a surface of the at least one daughter board is perpendicular to a surface of the mother board.

The above-noted EXAMPLE may further include any one or a combination of more than one of the following EXAMPLES: 28. The apparatus according to any EXAMPLE herein includes the at least one daughter board includes measurement circuitry, where the mother board is configured to operate with a plurality of different implementations of the at least one daughter board; and where the plurality of different implementations of the at least one daughter board includes different configurations and/or types of the at least one active device. 29. The apparatus according to any EXAMPLE herein where: the measurement circuitry is configured to measure electrical parameters of the at least one active device; and the measurement circuitry includes one or more current sensors, one or more voltage sensors, and/or one or more temperature sensors. 30. The apparatus according to any EXAMPLE herein where the at least one active device includes at least one transistor, diode, and/or power module. 31. The apparatus according to any EXAMPLE herein where: the mother board includes at least one mother board electrical connector and the at least one daughter board includes at least one daughter board electrical connector; and the at least one mother board electrical connector and the at least one daughter board electrical connector are configured to connect and exchange electrical signals, data, and/or electrical power. 32. The apparatus according to any EXAMPLE herein where: the mother board includes power connections configured to connect to a high-power power source; and the mother board includes connections between the power connections and the at least one mother board electrical connector. 33. The apparatus according to any EXAMPLE herein includes: a secondary component that includes a gate driver circuit, a controller, and/or a control board, where the mother board is configured to operate with a plurality of different types of implementations of the secondary component. 35. The apparatus according to any EXAMPLE herein where: the secondary component includes a secondary component electrical connector and the mother board includes a secondary component electrical connector; and the secondary component electrical connector of the mother board and the secondary component electrical connector of the secondary component are configured to connect and exchange electrical signals, data, and/or electrical power. 34. The apparatus according to any EXAMPLE herein includes: a secondary component that includes a gate driver circuit, a controller, and/or a control board, where the secondary component and the at least one daughter board are configured to connect and exchange electrical signals, data, and/or electrical power. 36. The apparatus according to any EXAMPLE herein where the mother board is configured to operate with a plurality of different types of implementations of a high-power power source. 37. The apparatus according to any EXAMPLE herein where the mother board includes a data connector that is configured to connect and exchange electrical signals and/or data with a separate device. 38. The apparatus according to any EXAMPLE herein includes at least one support structure configured to hold the at least one daughter board and the at least one support structure further configured to allow the at least one daughter board to be removed from the mother board. 39. The apparatus according to any EXAMPLE herein includes: a secondary component that includes a gate driver circuit, a controller, and/or a control board, where the mother board is configured to operate with a plurality of different types of implementations of the secondary component; and where the mother board is configured to operate with a plurality of different types of implementations of a high-power power source. 40. An evaluation platform includes the apparatus according to any EXAMPLE herein. 41. A product includes the apparatus according to any EXAMPLE herein, where the product includes one of a power system, a motor system, an automotive motor system, a charging system, an automotive charging system, a vehicle system, an industrial motor drive system, an embedded motor drive system, an uninterruptible power supply system, an AC-DC power supply system, a welder power supply system, a military system, an inverter system, an inverter for a wind turbine system, a solar power panel system, tidal power plant system, an electric vehicle (EVs) system, and/or a converter.

Aspects of the disclosure have been described above with reference to the accompanying drawings, in which aspects of the disclosure are shown. It will be appreciated, however, that this disclosure may, however, be embodied in many different forms and should not be construed as limited to the aspects set forth above. Rather, these aspects are provided so that this disclosure will be thorough and complete, and will fully convey the scope of the disclosure to those skilled in the art. Additionally, the various aspects described may be implemented separately. Moreover, one or more the various aspects described may be combined. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

Aspects of the disclosure may be implemented in any type of computing devices, such as, e.g., a desktop computer, personal computer, a laptop/mobile computer, a personal data assistant (PDA), a mobile phone, a tablet computer, cloud computing device, and the like, with wired/wireless communications capabilities via the communication channels.

Further in accordance with various aspects of the disclosure, the methods described herein are intended for operation with dedicated hardware implementations including, but not limited to, PCs, PDAs, semiconductors, application specific integrated circuits (ASIC), programmable logic arrays, cloud computing devices, and other hardware devices constructed to implement the methods described herein.

It should also be noted that the software implementations of the disclosure as described herein are optionally stored on a tangible storage medium, such as: a magnetic medium such as a disk or tape; a magneto-optical or optical medium such as a disk; or a solid state medium such as a memory card or other package that houses one or more read-only (non-volatile) memories, random access memories, or other re-writable (volatile) memories. A digital file attachment to email or other self-contained information archive or set of archives is considered a distribution medium equivalent to a tangible storage medium. Accordingly, the disclosure is considered to include a tangible storage medium or distribution medium, as listed herein and including art-recognized equivalents and successor media, in which the software implementations herein are stored.

Additionally, the various aspects of the disclosure may be implemented in a non-generic computer implementation. Moreover, the various aspects of the disclosure set forth herein improve the functioning of the system as is apparent from the disclosure hereof. Furthermore, the various aspects of the disclosure involve computer hardware that it specifically programmed to solve the complex problem addressed by the disclosure. Accordingly, the various aspects of the disclosure improve the functioning of the system overall in its specific implementation to perform the process set forth by the disclosure and as defined by the claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

1. A modular platform comprising:
a mother board;
at least one daughter board;
the at least one daughter board comprises at least one active device; and
the at least one daughter board comprises measurement circuitry,
wherein the mother board is configured to operate with a plurality of different implementations of the at least one daughter board; and
wherein the plurality of different implementations of the at least one daughter board comprising different configurations and/or types of the at least one active device.

2. The modular platform according to claim 1 wherein:
the measurement circuitry is configured to measure electrical parameters of the at least one active device; and
the measurement circuitry comprises one or more current sensors, one or more voltage sensors, and/or one or more temperature sensors.

3. The modular platform according to claim 1 wherein the at least one active device comprises at least one transistor, diode, and/or power module.

4. The modular platform according to claim 1 wherein:
the mother board comprises at least one mother board electrical connector and the at least one daughter board comprises at least one daughter board electrical connector; and
the at least one mother board electrical connector and the at least one daughter board electrical connector are configured to connect and exchange electrical signals, data, and/or electrical power.

5. The modular platform according to claim 4 wherein:
the mother board comprises power connections configured to connect to a high-power power source; and
the mother board comprises connections between the power connections and the at least one mother board electrical connector.

6. The modular platform according to claim 1 further comprising:
a secondary component that comprises a gate driver circuit, a controller, and/or a control board,
wherein the mother board is configured to operate with a plurality of different types of implementations of the secondary component.

7. The modular platform according to claim 6 wherein:
the secondary component comprises a secondary component electrical connector and the mother board comprises a secondary component electrical connector; and
the secondary component electrical connector of the mother board and the secondary component electrical connector of the secondary component are configured to connect and exchange electrical signals, data, and/or electrical power.

8. The modular platform according to claim 1 further comprising:
a secondary component that comprises a gate driver circuit, a controller, and/or a control board,
wherein the secondary component and the at least one daughter board are configured to connect and exchange electrical signals, data, and/or electrical power.

9. The modular platform according to claim 1 wherein the mother board is configured to operate with a plurality of different types of implementations of a high-power power source.

10. The modular platform according to claim 1 wherein the mother board comprises a data connector that is configured to connect and exchange electrical signals and/or data with a separate device.

11. The modular platform according to claim 1 further comprising at least one support structure configured to hold the at least one daughter board and the at least one support structure further configured to allow the at least one daughter board to be removed from the mother board.

12. The modular platform according to claim 1 further comprising:
a secondary component that comprises a gate driver circuit, a controller, and/or a control board,
wherein the mother board is configured to operate with a plurality of different types of implementations of the secondary component; and
wherein the mother board is configured to operate with a plurality of different types of implementations of a high-power power source.

13. An evaluation platform comprising the modular platform according to claim 1.

14. An application system comprising the modular platform according to claim 1, wherein the application system comprising one of a power system, a motor system, an automotive motor system, a charging system, an automotive charging system, a vehicle system, an industrial motor drive system, an embedded motor drive system, an uninterruptible power supply system, an AC-DC power supply system, a welder power supply system, a military system, an inverter system, an inverter for a wind turbine system, a solar power panel system, tidal power plant system, an electric vehicle (EVs) system, and/or a converter.

15. A method of implementing a modular platform comprising:
providing a mother board;
providing at least one daughter board;
configuring the at least one daughter board with at least one active device; and
configuring the at least one daughter board with measurement circuitry; and
configuring the mother board to operate with a plurality of different implementations of the at least one daughter board,
wherein the plurality of different implementations of the at least one daughter board comprising different configurations and/or types of the at least one active device.

16. The method of implementing the modular platform according to claim 15 further comprising:
measuring electrical parameters of the at least one active device with the measurement circuitry,
wherein the measurement circuitry comprises one or more current sensors, one or more voltage sensors, and/or one or more temperature sensors.

17. The method of implementing the modular platform according to claim 15 wherein the at least one active device comprises at least one transistor, diode, and/or power module.

18. The method of implementing the modular platform according to claim 15 further comprising:
configuring the mother board with at least one mother board electrical connector;
configuring the at least one daughter board with at least one daughter board electrical connector; and
connecting the at least one mother board electrical connector and the at least one daughter board electrical connector to exchange electrical signals, data, and/or electrical power.

19. The method of implementing the modular platform according to claim 18 further comprising:
configuring the mother board with power connections to connect to a high-power power source; and
configuring connections in the mother board between the power connections and the at least one mother board electrical connector.

20. The method of implementing the modular platform according to claim 15 further comprising:
providing a secondary component that comprises a gate driver circuit, a controller, and/or a control board; and
configuring the mother board to operate with a plurality of different types of implementations of the secondary component.

21. The method of implementing the modular platform according to claim 15 further comprising:
providing a secondary component that comprises a gate driver circuit, a controller, and/or a control board; and
wherein the secondary component and the at least one daughter board are configured to connect and exchange electrical signals, data, and/or electrical power.

22. The method of implementing the modular platform according to claim 15 wherein the mother board is configured to operate with a plurality of different types of implementations of a high-power power source.

23. The method of implementing the modular platform according to claim 15 further comprising configuring the mother board with a data connector to connect and exchange electrical signals and/or data with a separate device.

24. The method of implementing the modular platform according to claim 15 further comprising configuring at least one support structure configured to hold the at least one daughter board and the at least one support structure further configured to allow the at least one daughter board to be removed from the mother board.

25. The method of implementing the modular platform according to claim 15 further comprising:
implementing a secondary component that comprises a gate driver circuit, a controller, and/or a control board,
wherein the mother board is configured to operate with a plurality of different types of implementations of the secondary component; and
wherein the mother board is configured to operate with a plurality of different types of implementations of a high-power power source.

26. The method of implementing the modular platform according to claim 25 further comprising:
configuring the secondary component with a secondary component electrical connector;
configuring the mother board with a secondary component electrical connector; and
connecting the secondary component electrical connector of the mother board and the secondary component electrical connector of the secondary component to and exchange electrical signals, data, and/or electrical power.

27. An apparatus comprising:
a mother board;
at least one daughter board; and
the at least one daughter board comprises at least one active device,
wherein the apparatus is configured to facilitate high-power density by placing the at least one active device on or in the at least one daughter board such that a surface of the at least one daughter board is perpendicular to a surface of the mother board.

28.-40. (canceled)

41. A product comprising the apparatus according to claim 27, wherein the product comprises one of a power system, a motor system, an automotive motor system, a charging system, an automotive charging system, a vehicle system, an industrial motor drive system, an embedded motor drive system, an uninterruptible power supply system, an AC-DC power supply system, a welder power supply system, a military system, an inverter system, an inverter for a wind turbine system, a solar power panel system, tidal power plant system, an electric vehicle (EVs) system, and/or a converter.
